(19) United States
(12) Patent Application Publication
(10) Pub. No.: US 2009/0224360 A1
(43) Pub. Date: Sep. 10, 2009

(54) Semiconductor integrated circuit device and method of fabricating the same

(75) Inventor: Myoung-Soo Kim, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/379,664

(22) Filed: Feb. 26, 2009

(30) Foreign Application Priority Data
Mar. 4, 2008 (KR) 10-2008-0020162

(51) Int. Cl. H01L 23/525; H01L 23/544

(52) U.S. Cl. 257/529; 257/751; 257/E23.179; 257/E23.149

(57) ABSTRACT

A semiconductor integrated circuit device and a method of fabricating the same may be provided. The semiconductor integrated circuit device may include an align key pattern on a semiconductor substrate, a first passivation layer on the semiconductor substrate including the align key pattern and having a first opening exposing at least a portion of a top surface of the align key pattern, and a second passivation layer on the first passivation layer and within the first opening, wherein the second passivation layer covers the align key pattern exposed through the first opening.

### PRIORITY STATEMENT

This application claims priority under 35 U.S.C. § 119 to Korean Patent Application No. 10-2008-0020162, filed on Mar. 4, 2008, in the Korean Intellectual Property Office (KIPO), the entire contents of which are incorporated herein by reference.

### BACKGROUND

1. Field

Example embodiments relate to a semiconductor integrated circuit device and a method of fabricating the same, and more particularly, to a semiconductor integrated circuit device and method of fabricating the same with improved yield.

2. Description of the Related Art

Align keys may be used in various ways to measure alignment accuracy during fabrication of semiconductor integrated circuit devices. For example, align keys may be formed in scribe lines of a wafer and used for dividing dies. Align keys may also be used to align subsequent masks to precise positions where patterns will be formed. Furthermore, align keys may be used to correctly position preformed chips during the assembly.

For example, align keys may be important for fabrication of high-precision semiconductor devices. If align keys are not properly recognized, precise alignment may not be allowed, thereby causing defects in a semiconductor device.

### SUMMARY

Example embodiments provide a semiconductor integrated circuit device with improved yield. Example embodiments also provide a method of fabricating a semiconductor integrated circuit device with improved yield. Example embodiments may provide a semiconductor integrated circuit device including an align key that may be easily recognizable and may be protected from damage during fabrication of a semiconductor integrated circuit device.

According to example embodiments, a semiconductor integrated circuit device may include an align key pattern on a semiconductor substrate, a first passivation layer on the semiconductor substrate including the align key pattern and having a first opening exposing at least a portion of a top surface of the align key pattern, and a second passivation layer on the first passivation layer and within the first opening, wherein the second passivation layer covers the align key pattern exposed through the first opening.

According to example embodiments, a method of fabricating a semiconductor integrated circuit device may include forming at least one pattern on a semiconductor substrate, forming a first passivation layer on the semiconductor substrate having the at least one pattern, patterning the first passivation layer to form a first opening exposing at least a portion of a top surface of the at least one pattern, and forming a second passivation layer covering the first passivation layer and the portion of the top surface of the at least one pattern exposed through the first opening, wherein the second passivation layer may be thinner than the first passivation layer.

### BRIEF DESCRIPTION OF THE DRAWINGS

Example embodiments will be more clearly understood from the following detailed description taken in conjunction with the accompanying drawings. FIGS. 1A-9 represent non-limiting, example embodiments as described herein.

FIG. 1A is a plan view of a semiconductor integrated circuit device according to example embodiments;

FIG. 1B is a cross-sectional view taken along line I-I′ of FIG. 1A;

FIGS. 2A-4B illustrate a method of fabricating a semiconductor integrated circuit device according to example embodiments;

FIGS. 5 and 6 illustrate the configuration of a semiconductor integrated circuit device according to example embodiments; and

FIGS. 7-9 are cross-sectional views illustrating a method of fabricating a semiconductor integrated circuit device according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will be described more fully hereinafter with reference to the accompanying drawings, in which example embodiments are shown. Example embodiments may, however, be embodied in different forms and should not be construed as limited to example embodiments set forth herein. Rather, example embodiments are provided so that this disclosure will be thorough and complete, and will fully convey the scope of example embodiments to those skilled in the art. In the drawings, the thickness of layers and regions are exaggerated for clarity. In addition, when a layer is described to be formed on another layer or on a substrate, this means that the layer may be formed on the other layer or on the substrate, or a third layer may be interposed between the layer and the other layer or the substrate. Like numbers refer to like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

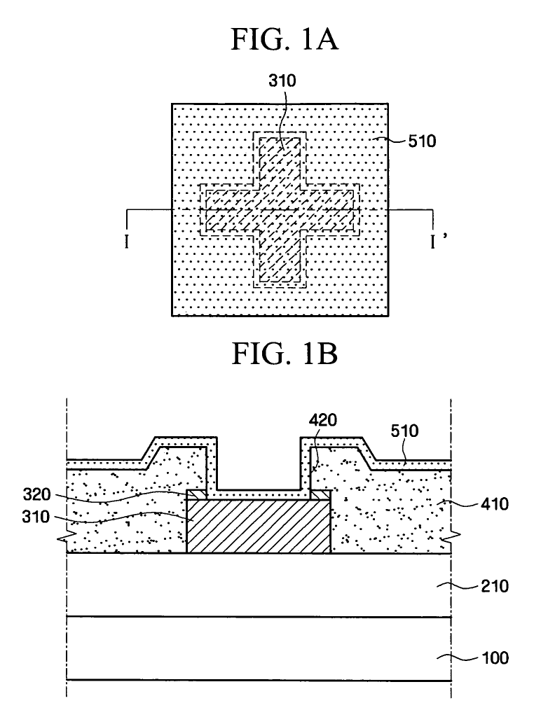

Hereinafter, a semiconductor integrated circuit device according to example embodiments will be explained in more detail with reference to FIGS. 1A and 1B. FIG. 1A is a plan view of a semiconductor integrated circuit device according to example embodiments, and FIG. 1B is a cross-sectional view taken along line I-I′ of FIG. 1A.

Referring to FIGS. 1A and 1B, the semiconductor integrated circuit device according to example embodiments may include a conductive semiconductor substrate 100, an align key pattern 310 formed above the semiconductor substrate 100, a first passivation layer 410 formed on the semiconductor substrate 100, and a second passivation layer 510 overlying the first passivation layer 410.

The semiconductor substrate 100 may be a silicon substrate, SOI (silicon on insulator) substrate, Ga-As (Gallium-Arsenide) substrate, Si-Ge (Silicon Geranium) substrate, ceramic substrate, quartz substrate, or glass substrate for a display device. In addition, the semiconductor substrate 100 may be typically of a P-type. Although not shown, a P-type epitaxial layer may be allowed to grow on the semiconductor substrate 100.

The semiconductor integrated circuit device further may include an interlayer insulating layer 210 formed over the semiconductor substrate 100. The interlayer insulating layer 210 may be a mono- or multi-layer. In addition, although not shown, transistors, contact holes and/or metal wirings may be formed in the interlayer insulating layer 210, which is, however, well-known to those of ordinary skill in the art, and thus a detailed description thereof may be omitted herein.

The align key pattern 310 may be formed on the interlayer insulating layer 210. Although FIG. 1 shows the align key pattern 310 having a cross shape, the align key pattern 310 may not be limited thereto, and may have other various shapes. The align key pattern 310 may be formed of metal, e.g., aluminum (Al). A barrier layer 320 may be formed of titanium nitride (TiN) so as to surround the align key pattern 310. Alternatively, the entire barrier layer 320 may be etched away when forming an opening 420.

The first passivation layer 410 may be formed over the conductive semiconductor substrate 100 including the align key pattern 310 formed thereon. The first passivation layer 410 may be formed of oxide, nitride, or a combination thereof. The first passivation layer 410 may also be formed thicker than the align key pattern 310 so as to cover a periphery of the semiconductor substrate 100 on which the align key pattern 310 has been formed. Thus, the first passivation layer 410 may be formed of a material having an improved gap fill capability, e.g., High Density Plasma (HDP) to a thickness of about 3,000 to about 20,000 Å.

The first passivation layer 410 may have an opening 420 formed on a top surface of the align key pattern 310 so as to expose at least a portion of the top surface thereof. The opening 420 may also extend down into the barrier layer 320 so that the top surface of the align key pattern 310 may be exposed at the bottom of the opening 420. If the opening 420 has the same width as the align key pattern 310, the barrier layer 320 may be entirely removed.

The second passivation layer 510 may be formed over the first passivation layer 410 and within the opening 420 so as to cover the top surfaces of the first passivation layer 410 and align key pattern 310. The second passivation layer 510 may be formed of oxide or nitride, e.g., SiN, to a thickness of about 500 to about 5,000 Å, which is less than the thickness of the first passivation layer 410. The second passivation layer 510 may be formed of various materials that may be easy to handle regardless of their gap fill capabilities using chemical vapor deposition (CVD) or physical vapor deposition (PVD).

According to example embodiments, the second passivation layer 510 may cover the top surface of the align key pattern 310 so as to more easily distinguish the align key pattern 310 from the periphery of the semiconductor substrate 100 covered by the first passivation layer 410, which is significantly thicker than the second passivation layer 510. Further, if the align key pattern 310 and the barrier layer 320 are formed of Al and TiN, respectively, the align key pattern 310 may be more readily recognizable due to a relatively large difference in luminance between the two metals. Because the second passivation layer 510 is thinner than the first passivation layer 410, the align key pattern 310 may be readily recognizable by alignment equipment.

Furthermore, because the align key pattern 310 is covered by the second passivation layer 510 without being exposed, preventing or reducing damage to the align key pattern 310 during subsequent processes may be possible. For example, the semiconductor integrated circuit device according to example embodiments may include the align key pattern 310 that may be protected from damage and may be readily recognizable by alignment equipment, thus providing an improved yield.

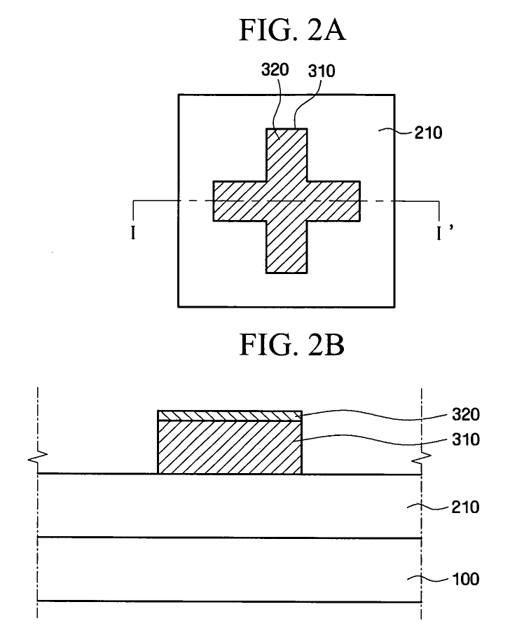

A method of fabricating a semiconductor integrated circuit device according to example embodiments will now be described in detail with reference to FIGS. 2A-4B. FIGS. 2A-4B illustrate a method of fabricating a semiconductor integrated circuit device according to example embodiments. FIGS. 2B, 3B, and 4B are cross-sectional views taken along line I-I′ of FIGS. 2A, 3A, and 4A, respectively.

Referring to FIGS. 2A and 2B, the align key pattern 310 may be formed on the semiconductor substrate 100. For example, the interlayer insulating layer 210 may be deposited over the semiconductor substrate 100. While a transistor, an insulating layer, a contact hole, and metal wiring may be formed within the interlayer insulating layer 210, it may be well-known to those of ordinary skill in the art, and thus a detailed description thereof is omitted herein. Subsequently, a conductive layer (not shown) and a barrier conductive layer (not shown) may be deposited over the interlayer insulating layer 210 and patterned to form the align key pattern 310 and the barrier layer 320, which is formed on the align key pattern 310 and may have the same pattern as the align key pattern 310.

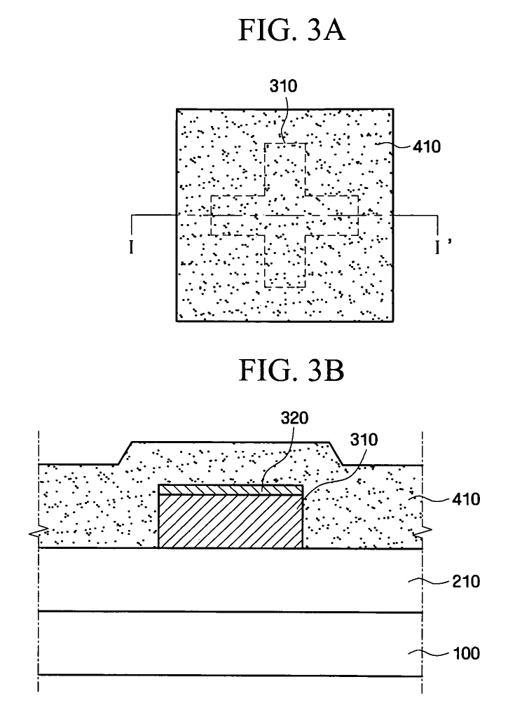

Referring to FIGS. 3A and 3B, the first passivation layer 410 may be formed over the semiconductor substrate 100 including the align key pattern 310 formed thereon. In example embodiments, the first passivation layer 410 may be formed of oxide, nitride, or a combination thereof using Plasma Enhanced Atomic Layer Deposition (PEALD), plasma CVD, or thermal CVD. The first passivation layer 410 may be formed of a material having an improved gap fill capability, e.g., HDP using a deposition technique that may achieve an improved gap fill. The first passivation layer 410 may also be deposited higher than the align key pattern 310 so as to cover the periphery of the align key pattern 310.

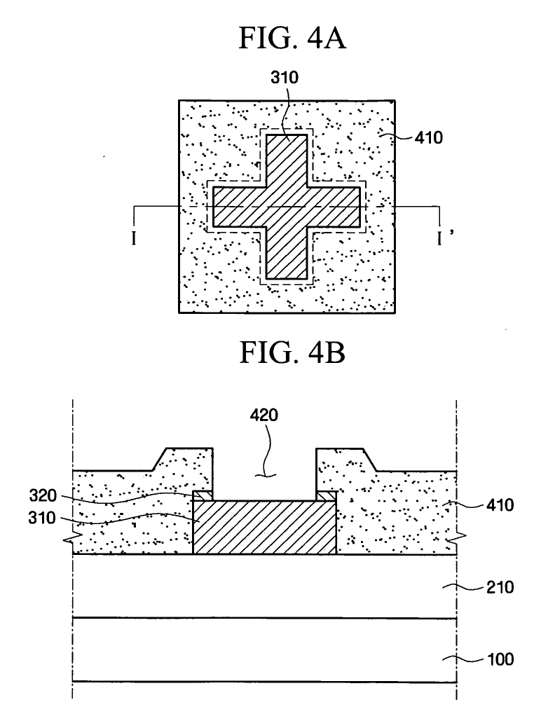

Referring to FIGS. 4A and 4B, the first passivation layer 410 may be subsequently patterned to form the opening 420 exposing at least a portion of the top surface of the align key pattern 310. For example, the first passivation layer 410 may be patterned using a photolithographic process. The opening 420 may expose the entire top surface of the align key pattern 310. The barrier layer 320 may be etched while etching the first passivation layer 410 to form the opening 420, so that the top surface of the align key pattern 310 may be exposed at the bottom of the opening 420. The opening 420 may be formed by wet etching or dry etching, e.g., Reactive Ion Etching (RIE).

Returning to FIGS. 1A and 1B, after patterning the first passivation layer 410 to form the opening 420, the second passivation layer 510 may cover the first passivation layer 410 and the top surface of the align key pattern 310 exposed through the opening 420. For example, the second passivation layer 510 may be formed by depositing oxide or nitride using CVD or PVD. Because the second passivation layer 510 is thinner than the first passivation layer 410, the align key pattern 310 may be more easily recognizable by alignment equipment even though the top surface of the align key pattern 310 is covered by the second passivation layer 510. Further, the second passivation layer 510 may protect the exposed top surface of the align key pattern 310 against damage.

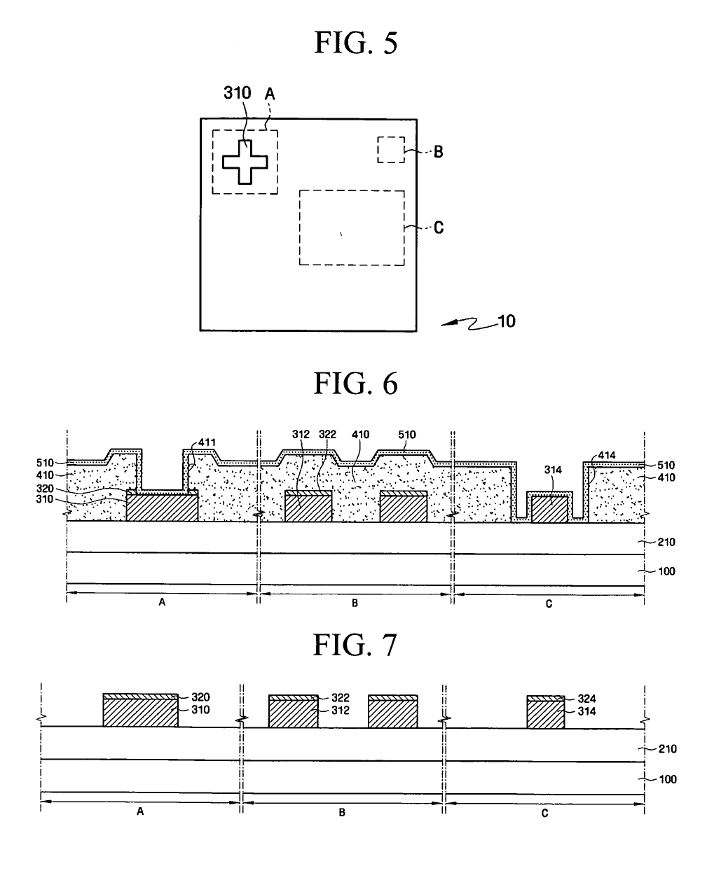

A semiconductor integrated circuit device according to example embodiments will now be described with reference to FIGS. 5 and 6. FIGS. 5 and 6 illustrate the configuration of a semiconductor integrated circuit device according to example embodiments. Referring to FIGS. 5 and 6, the semiconductor integrated circuit device according to example embodiments may include a semiconductor chip 10. The semiconductor chip 10 may include an align key region A having an align key pattern 310 formed thereon, a wiring region B having a wiring pattern 312 formed thereon, and a fuse region C having a fuse 314 formed thereon. For example, the align key region A, the wiring region B, and the fuse region 314 may be defined on the semiconductor chip 10.

FIG. 6 is a cross-sectional view illustrating the align key region A, the wiring region B, and the fuse region C shown in FIG. 5. An interlayer insulating layer 210 may be formed over a semiconductor substrate 100 and may include transistors, an interlayer insulating layer, a contact hole, and metal wirings, which is, however, well-known to those of ordinary skill in the art, and thus a detailed description thereof may be omitted herein. The align key pattern 310 may be formed on a portion of the interlayer insulating layer 210 on the align key region A. The wiring pattern 312 may be formed on a portion of the interlayer insulating layer 210 on the wiring region B. The fuse 314 may be formed on a portion of the interlayer insulating layer 210 on the fuse region C.

The align key pattern 310, the wiring pattern 312, and the fuse 314 may be formed on the interlayer insulating layer 210 with the same thickness. Even with different heights, the align key pattern 310, the wiring pattern 312, and the fuse 314 may be formed of the same material, for example, the same metal, e.g., Al. The metal used to form the align key pattern 310, the wiring pattern 312, and the fuse 314 may be the same as that used in the final step of the wiring process of the semiconductor chip 10.

Barrier layers 320 and 322 may be formed on a portion of a top surface of the align key pattern 310 and the wiring pattern 312, respectively. For example, the barrier layers 320 and 322 may be formed of TiN. The barrier layers 320 and 322 may act as an etch stop during patterning the align key pattern 310, the wiring pattern 312, and the fuse 314 and prevent or reduce diffusion and oxidation of the wiring pattern 312. For example, the barrier layers 320 and 322 may be needed during a patterning process as well as for protecting the wiring pattern 312. However, if the barrier layer 320 is formed on the align key pattern 310, recognition performance of alignment equipment may be degraded. Thus, the barrier layer may be formed only on a periphery of the align key pattern 310.

A first passivation layer 410 may be formed over the interlayer insulating layer 210 including the align key pattern 310, the wiring pattern 312, and the fuse 314 formed thereon. The first passivation layer 410 may also be deposited higher than the align key pattern 310, the wiring pattern 312, and the fuse 314 so as to cover the peripheries of the align key pattern 310, the wiring pattern 312, and the fuse 314. Thus, the first passivation layer 410 may be formed of a material having an improved gap fill capability, e.g., High Density Plasma (HDP). The first passivation layer 410 may have a thickness in a range of about 3,000 to about 20,000 Å. For example, the first passivation layer may be formed of one of oxide, nitride, and a combination thereof.

The first passivation layer 410 may have first and second openings 411 and 414. The first opening 411 may be formed to the top surface of the align key pattern 310 so as to expose at least a portion of the top surface thereof. The second opening 414 may expose the entire top surface of the fuse 314 as well as a portion of a periphery of the fuse 314. In example embodiments, the barrier layer 320, which is formed in the first and second openings 411 and 414, may be removed.

A second passivation layer 510 may be formed on the first passivation layer 410 and within the first and second openings 411 and 414. For example, the second passivation layer 510 may cover the top surfaces of the first passivation layer 410, align key pattern 310, and fuse 314. The second passivation layer 510 may be, for example, oxide or nitride. The second passivation layer 510 may be thinner than the first passivation layer 410. The second passivation layer 510 may have a thickness in a range of about 500 to about 5,000 Å. The second passivation layer 510 may be formed using chemical vapor deposition (CVD) or physical vapor deposition (PVD). The second passivation layer 510 may not be necessarily formed of a material having an improved gap fill capability and may be formed of various materials that may be relatively easy to handle, regardless of their gap fill capabilities.

According to example embodiments, the align key pattern 310, the wiring pattern 312, and the fuse 314 may be formed of the same metal and the barrier layer 322 may be formed only on the wiring pattern 312 instead of the align key pattern 310. Thus, degradation in recognition performance of alignment equipment may be prevented or reduced. Further, the second passivation layer 510 may be formed only on the align key pattern 310, thereby improving the recognition capability of the align key pattern 310 while protecting the alignment pattern 310 against damage.

The first passivation layer 410 having an improved gap fill capability may be filled between the wiring patterns 312 of the wiring region B and the fuse 314 may be exposed so that it may easily short out and protected by the second passivation layer 510. For example, the align key pattern 310, the wiring pattern 312, and the fuse 314 may be formed on the regions of the semiconductor chip 10 in a form that may be most suitable and appropriate therefor.

A method of fabricating a semiconductor integrated circuit device according to example embodiments will be described with reference to FIGS. 5-9. FIGS. 7-9 are cross-sectional views illustrating a method of fabricating a semiconductor integrated circuit device according to example embodiments. Referring to FIG. 7, the align key pattern 310, the wiring patterns 312, the fuse 314 may be formed on portions of the interlayer insulating layer 210 on the align key region A, the wiring region B, and the fuse region C, respectively.

For example, the align key pattern 310, the wiring patterns 312, the fuse 314 may be formed simultaneously by depositing and patterning a conductive layer (not shown) and a conductive barrier layer (not shown) on the interlayer insulating layer 210. Thus, the align key pattern 310, the wiring patterns 312, the fuse 314 may be formed of the same material, and barrier layers 320, 322, and 324 may be formed on the align key pattern 310, the wiring patterns 312, and the fuse 314. In example embodiments, the align key pattern 310, the wiring patterns 312, the fuse 314 may have the same or different heights.

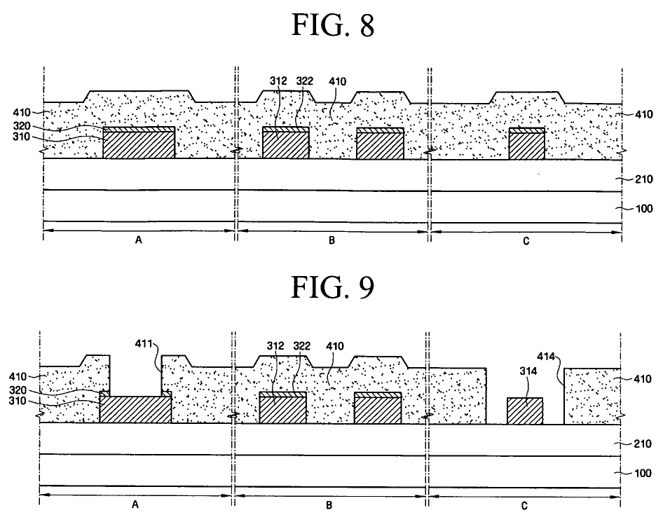

Referring to FIG. 8, the first passivation layer 410 may be formed over the interlayer insulating layer 210 having the align key pattern 310, the wiring patterns 312, and the fuse 314 formed thereon. The first passivation layer 410 may be formed of a material having an improved gap fill capability to a height that may be greater than the align key pattern 310, the wiring patterns 312, and the fuse 314.

Referring to FIG. 9, the first passivation layer 410 may be patterned to form the first opening 411 exposing at least a portion of a top surface of the align key pattern 310 and the second opening 414 exposing the entire top surface of the fuse 314 as well as a portion of a periphery of the fuse 314. During a photolithographic process for forming the first and second openings 411 and 414, the barrier layers 320 and 324 may be etched together with the first passivation layer 410. Thus, the barrier layers 320 and 324 exposed within the first and second openings 411 and 414 may be entirely etched to expose the top surface of the align key pattern 310 and the top surface and sides of the fuse 314. A portion of the barrier layer 320 may reside on top edges of the align key pattern 310.

Returning to FIG. 6, the second passivation layer 510 may be subsequently formed on the first passivation layer 410, the first opening 421, the top surface of the align key pattern 310 exposed through the first opening 421, the second opening 424, and the top surface of the fuse 324 exposed through the second opening 424. The second passivation layer 510 may also be formed thinner than the first passivation layer 410 to protect the align key pattern 310 and the fuse 314. For example, the second passivation layer 510 may be sufficiently thin so as to prevent or reduce degradation in recognition capability of the align key pattern 310 and more easily enable shorting out.

The align key pattern 310 according to example embodiments may be, but not limited to, a COG (chip on glass) align key pattern. Because the COG align key pattern is formed on top of the semiconductor chip 10, the function of the second passivation layer 510, for example, protecting the align key pattern 310 and the fuse 314, may become important. In addition, in a case where a COG (chip on glass) align key pattern is used as the align key pattern 310, the align key pattern 310 may be formed of Al at the same time with the bump of the semiconductor chip 10.

As described above, a semiconductor integrated circuit device and method of fabricating the same according to example embodiments may have several advantages. In the semiconductor integrated circuit device, the top surface of an align key pattern may be covered by a thin second passivation layer so as to more easily distinguish the align key pattern from the periphery of the semiconductor substrate covered by the first passivation layer that may be thicker than the second passivation layer. Further, if the align key pattern and the barrier layer is formed of Al and TiN, respectively, the align key pattern may be more readily recognizable due to a relatively large difference in luminance between the two metals. Because the second passivation layer is thinner than the first passivation layer, the align key pattern may be more readily recognizable by alignment equipment.

Further, because the top surface of the align key pattern is covered by the second passivation layer without being exposed, protecting the align key pattern against damage during subsequent processes may be possible. For example, the semiconductor integrated circuit device according to example embodiments provides the align key pattern that may be protected against damage and may be readily recognizable by alignment equipment, thereby achieving an improved yield.

While example embodiments have been particularly shown and described with reference to example embodiments thereof, it will be understood by those of ordinary skill in the art that various changes in form and details may be made therein without departing from the spirit and scope of example embodiments as defined by the following claims. It may be therefore desired that example embodiments be considered in all respects as illustrative and not restrictive, reference being made to the appended claims rather than the foregoing description to indicate the scope of example embodiments.

1. A semiconductor integrated circuit device comprising:
an align key pattern on a semiconductor substrate;
a first passivation layer on the semiconductor substrate including the align key pattern and having a first opening exposing at least a portion of a top surface of the align key pattern; and
a second passivation layer on the first passivation layer and within the first opening,
wherein the second passivation layer covers the align key pattern exposed through the first opening.

2. The device of claim 1, wherein the align key pattern is formed of a metal.

3. The device of claim 2, wherein the align key pattern is formed of aluminum (Al).

4. The device of claim 2, further comprising:
a barrier layer on the align key pattern.

5. The device of claim 4, wherein the barrier layer is titanium nitride (TiN).

6. The device of claim 4, wherein the barrier layer is between the first passivation layer and the align key pattern and the second passivation layer is in contact with the align key pattern at a bottom of the first opening.

7. The device of claim 1, wherein the first passivation layer is formed of one of oxide, nitride, and a combination thereof.

8. The device of claim 1, wherein the second passivation layer is formed of one of oxide and nitride.

9. The device of claim 1, wherein the second passivation layer is thinner than the first passivation layer.

10. The device of claim 9, wherein the first passivation layer has a thickness in a range of about 3,000 to about 20,000 □.

11. The device of claim 9, wherein the second passivation layer has a thickness in a range of about 500 to about 5,000 □.

12. The device of claim 1, wherein the thickness of the first passivation layer is greater than that of the align key pattern.

13. The device of claim 1, further comprising:
a fuse on the semiconductor substrate,
wherein the first passivation layer is formed on a top surface of the fuse and has a second opening exposing at least a portion of the top surface of the fuse, and
the second passivation layer covers the second opening and the fuse exposed through the second opening.

14. The device of claim 1, further comprising:
a wiring pattern on the semiconductor substrate,
wherein the align key pattern has the same height and is formed of the same material as the wiring pattern.

15-24. (canceled)
